(19) United States
(12) Patent Application Publication
(10) Pub. No.: US 2026/0050027 A1
(43) Pub. Date: Feb. 19, 2026

(54) TEST HANDLER AND METHOD FOR TESTING SEMICONDUCTOR PACKAGES USING THE TEST HANDLER

(71) Applicant: SEMES CO., LTD., Chungcheongnam-do (KR)

(72) Inventors: Harkryong KIM, Chungcheongnam-do (KR); Jongsung PARK, Chungcheongnam-do (KR)

(21) Appl. No.: 19/276,407

(22) Filed: Jul. 22, 2025

(30) Foreign Application Priority Data
Aug. 14, 2024 (KR) 10-2024-0109442

(51) Int. Cl. G01R 31/26

(52) U.S. Cl. CPC G01R 31/2601

(57) ABSTRACT

The present disclosure relates to a test handler and a method for testing semiconductor packages using the test handler capable of performing an electrical inspection process on semiconductor packages. The disclosure may include a loader unit to detach a semiconductor package to be tested from a first ring frame on which semiconductor packages to be tested are placed, or to attach a tested semiconductor package to a second ring frame; a tester unit to test the semiconductor package loaded from the loader unit and to unload the tested semiconductor package back to the loader unit; and a shuttle unit installed to connect the loader unit and the tester unit, to transfer the semiconductor package to the tester unit or to the loader unit, and to preheat or cool the semiconductor package during transfer.

### CROSS-REFERENCE TO RELATED PATENT APPLICATION

This application claims the benefit of Korean Patent Application No. 10-2024-0109442, filed on Aug. 14, 2024, in the Korean Intellectual Property Office, the disclosure of which is incorporated herein in its entirety by reference.

### BACKGROUND OF THE INVENTION

### 1. Field of the Disclosure

The present disclosure relates to a test handler and a test method for testing semiconductor packages using a test handler, and more particularly, to a test handler capable of performing an electrical inspection process on semiconductor packages and test methods for semiconductor packages.

### 2. Description of the Related Art

Generally, semiconductor devices can be formed on a silicon wafer used as a semiconductor substrate by repeatedly performing a series of manufacturing processes. The semiconductor devices formed as described above can be manufactured into semiconductor packages through a dicing process, a bonding process, and a packaging process.

The semiconductor packages manufactured as described above may be classified as good products or defective products through electrical characteristic inspection. In the electrical characteristic inspection, a test handler for handling semiconductor devices and a test apparatus for inspecting the semiconductor packages may be used.

Recently, as various types of semiconductor devices have been developed, there is a growing demand for electrical inspection processes for the semiconductor devices that have been individualized through the dicing process, and consequently, a demand for inspection apparatuses to perform such inspection is also increasing. For example, in the case of high bandwidth memory (HBM) devices formed on a wafer, an electrical inspection process may be required after individualization through the dicing process.

### SUMMARY OF THE INVENTION

The present disclosure aims to address the above-described problems, among others, and an object thereof is to provide a test handler and test method for semiconductor packages that can perform electrical inspection processes on high bandwidth memory (HBM) devices. However, such an object is illustrative and does not limit the scope of the present disclosure.

According to an embodiment of the present disclosure, a test handler is provided. The test handler may include a loader unit to detach a semiconductor package to be tested from a first ring frame on which the semiconductor packages to be tested are placed, or to attach a tested semiconductor package to a second ring frame; a tester unit to test the semiconductor package loaded from the loader unit and to unload the tested semiconductor package back to the loader unit; and a shuttle unit installed to connect the loader unit and the tester unit, to transfer the semiconductor package to the tester unit or to the loader unit, and to preheat or cool the semiconductor package during transfer.

According to an embodiment of the present disclosure, the loader unit may include a gripper unit to draw the first ring frame, on which a plurality of semiconductor packages to be tested are placed, from a first cassette, or to store the second ring frame, on which the tested semiconductor packages are placed, into a second cassette; a ring frame expander to place the first ring frame drawn from the first cassette and to expand a dicing tape to which the semiconductor packages are attached so as to increase spacing between the semiconductor packages; a ring frame stage on which the second ring frame to which the tested semiconductor packages are to be attached is placed; a load picker unit to pick up a semiconductor package from the first ring frame placed on the ring frame expander and to transfer it to the shuttle unit; and an unload picker unit to pick up the semiconductor package tested by the tester unit and transferred back to the loader unit via the shuttle unit and to transfer it onto the second ring frame placed on the ring frame stage.

According to an embodiment of the present disclosure, the load picker unit may include a load gantry formed to extend linearly along one side of the ring frame expander and the ring frame stage, which are arranged in a row; and a load picker installed to be slidable along the load gantry, to pick up the semiconductor package from the first ring frame placed on the ring frame expander. The unload picker unit may include an unload gantry formed to extend linearly along the opposite side of the ring frame expander and the ring frame stage, arranged in a row, so as to be parallel to the load gantry; and an unload picker installed to be slidable along the unload gantry, to pick up the semiconductor package placed on the shuttle unit. The gripper unit may include a gripper gantry formed to extend in a direction perpendicular to the extension directions of the load gantry and the unload gantry, which are formed in parallel, and to connect the load gantry and the unload gantry; and a gripper installed to be slidable along the gripper gantry, formed with a gripping portion to grip one side of the first or second ring frame, and to draw the first ring frame from the first cassette to the ring frame expander or to store the second ring frame from the ring frame stage into the second cassette.

According to an embodiment of the present disclosure, the unload picker unit may further include an unload vision inspection unit installed below the path of movement of the unload picker and to perform a vision inspection of the exterior of the semiconductor package picked up and transferred by the unload picker, and wherein the unload picker is to correct a pickup error of the semiconductor package based on a result of the vision inspection by the unload vision inspection unit.

According to an embodiment of the present disclosure, the shuttle unit may include a shuttle rail unit formed to extend in a direction perpendicular to the extension directions of the load gantry and the unload gantry, which are formed in parallel, and extending to the tester unit; and a shuttle stage installed to be slidable along the shuttle rail unit and to transfer the semiconductor package between the loader unit and the tester unit.

According to an embodiment of the present disclosure, the shuttle stage may include a heater unit installed inside the shuttle stage, to heat the semiconductor package placed on the upper surface of the shuttle stage; and a cooling unit including a nozzle installed on a side of the shuttle stage, to spray air toward the semiconductor package placed on the upper surface of the shuttle stage to cool the semiconductor package.

According to an embodiment of the present disclosure, the tester unit may include a tester module to test the semiconductor package; an align picker unit to pick up the semiconductor package transferred to the tester unit via the shuttle unit; and a test stage installed to be slidable between the align picker unit and the tester module, to move the semiconductor package to a position corresponding to the tester module or to a position corresponding to the align picker unit, wherein the align picker unit places the semiconductor package on the test stage for testing, or to pick up the tested semiconductor package from the test stage and place it on the shuttle unit.

According to an embodiment of the present disclosure, the align picker unit may include an align gantry formed to extend linearly in a direction between one end of the shuttle unit and a position corresponding to the sliding movement path of the test stage; an align picker installed to be slidable along the align gantry, to pick up the semiconductor package transferred via the shuttle unit and place it onto the test stage, or to pick up the tested semiconductor package from the test stage and place it onto the shuttle unit; and an align vision inspection unit installed above the align picker having a hollow portion, to perform a vision inspection of an internal pattern on the upper surface of the semiconductor package picked up by the align picker through the hollow portion, wherein the align picker is to correct a pickup error of the semiconductor package based on a result of the vision inspection of the internal pattern by the align vision inspection unit.

According to an embodiment of the present disclosure, the align picker unit may be to pre-calculate and store deformation data for the test stage according to temperature, and when placing the semiconductor package on the test stage, to calculate real-time deformation amount of the test stage based on the measured real-time temperature and the deformation data, and to offset the placement position of the semiconductor package by the real-time deformation amount, thereby placing the semiconductor package on the test stage.

According to an embodiment of the present disclosure, a method for testing semiconductor packages using a test handler comprising a loader unit to detach a semiconductor package to be tested from a first ring frame on which semiconductor packages to be tested are placed, or to attach a tested semiconductor package to a second ring frame, a tester unit to test the semiconductor package loaded from the loader unit and to unload the tested semiconductor package back to the loader unit, and a shuttle unit installed to connect the loader unit and the tester unit, to transfer the semiconductor package to the tester unit or to the loader unit, and to preheat or cool the semiconductor package during transfer, the method comprising the steps of: (a) transferring the first ring frame, on which the semiconductor packages to be tested are placed, from a first cassette to a ring frame expander of the loader unit using the gripper unit of the loader unit; (b) detaching the semiconductor package from the first ring frame using a load picker unit; (c) placing the semiconductor package onto a shuttle stage of the shuttle unit; (d) picking up the semiconductor package, placed on the shuttle stage that has moved to the tester unit, and placing it onto a test stage using the align picker unit of the tester unit; (e) moving the test stage, on which the semiconductor packages to be tested are placed, to a position corresponding to a tester module; (f) electrically contacting the tester module with the semiconductor packages placed on the test stage and testing the semiconductor packages; (g) moving the test stage, on which the tested semiconductor packages are placed, to a position corresponding to the align picker unit; (h) picking up the tested semiconductor package from the test stage and placing it onto the shuttle stage using the align picker unit; (i) picking up the tested semiconductor package from the shuttle stage, which has moved to the loader unit and attaching it to the second ring frame using an unload picker unit; and (j) storing the second ring frame, on which the tested semiconductor packages are placed, into a second cassette using the gripper unit.

### BRIEF DESCRIPTION OF THE DRAWINGS

The above and other features and advantages of the present invention will become more apparent by describing in detail embodiments thereof with reference to the attached drawings.

FIG. 1 is a schematic diagram illustrating the configuration of a test handler according to an embodiment of the present disclosure.

FIG. 2 is a schematic diagram illustrating the configuration of the load picker unit of the test handler in FIG. 1.

FIG. 3 is a schematic diagram illustrating the configuration of the unload picker unit of the test handler in FIG. 1.

FIG. 4 is a schematic diagram illustrating the configuration of the shuttle unit of the test handler in FIG. 1.

FIG. 5 is a schematic diagram illustrating the configuration of the align picker unit of the test handler in FIG. 1.

FIG. 6 is a schematic diagram illustrating the configuration of a test handler according to another embodiment of the present disclosure.

FIG. 7 is a flowchart sequentially illustrating a method for inspecting semiconductor packages according to another embodiment of the present disclosure.

### DETAILED DESCRIPTION OF THE INVENTION

Hereinafter, preferred embodiments of the present disclosure will be described in detail with reference to the accompanying drawings.

The embodiments of the present disclosure are provided to fully explain the disclosure to those skilled in the art, and the following embodiments may be modified in various ways. The scope of the present disclosure is not limited to the following embodiments. Rather, these embodiments are provided to enhance the completeness and understanding of this disclosure and to fully convey the spirit of the disclosure to those skilled in the art. Also, the thickness and size of each layer shown in the drawings may be exaggerated for the sake of convenience and clarity of explanation.

Hereinafter, the embodiments of the present disclosure are described with reference to the drawings that schematically illustrate ideal embodiments of the disclosure. In the drawings, for example, variations in the illustrated shapes may be expected depending on manufacturing techniques and/or tolerances. Accordingly, the embodiments of the disclosure should not be construed as limited to the specific shapes of regions illustrated herein but should be understood to include changes in shape that may occur due to manufacturing processes.

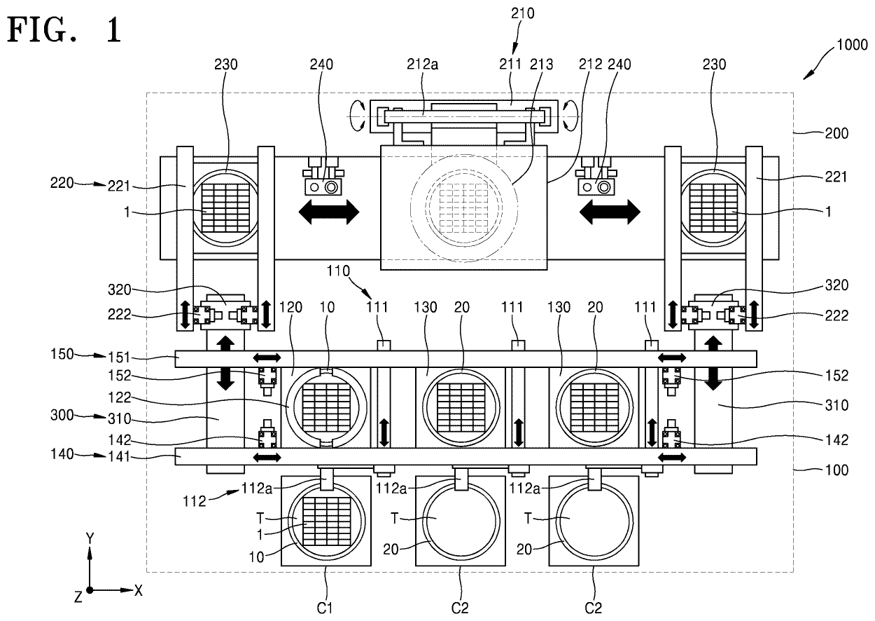

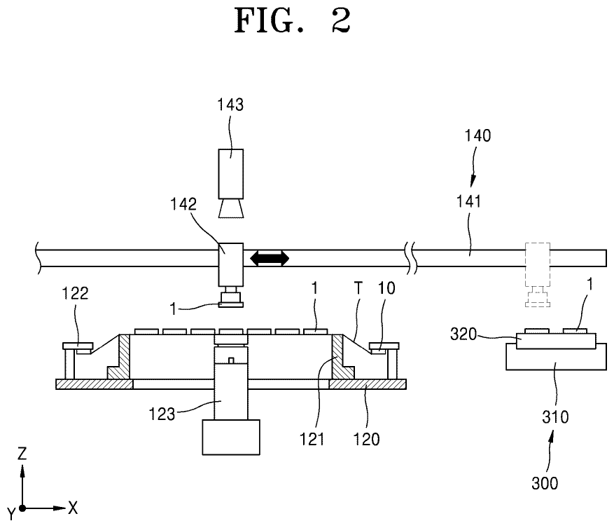

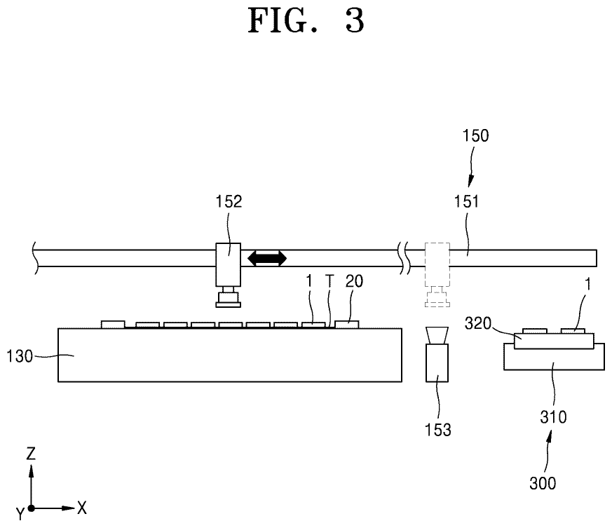

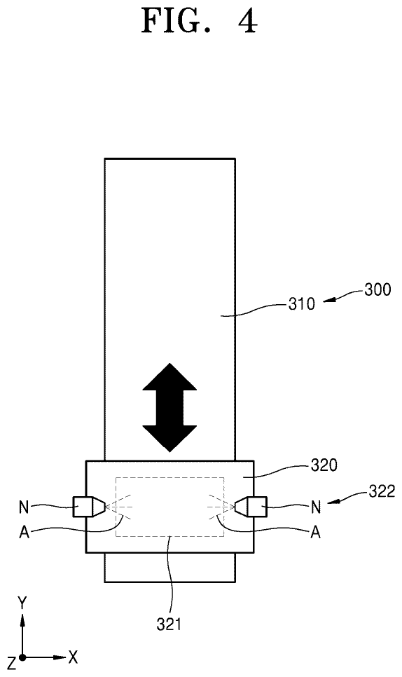

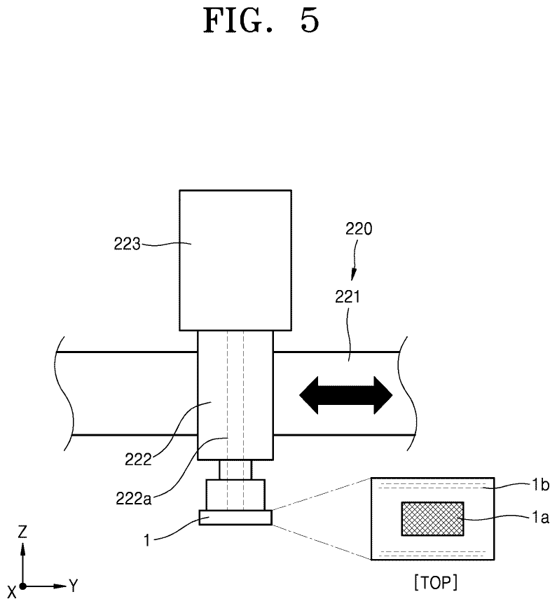

FIG. 1 is a schematic diagram illustrating the configuration of a test handler 1000 according to an embodiment of the present disclosure. FIG. 2 is a schematic diagram illustrating the configuration of a load picker unit 140 of the test handler 1000 shown in FIG. 1. FIG. 3 is a schematic diagram illustrating the configuration of an unload picker unit 150 of the test handler 1000 shown in FIG. 1. FIG. 4 is a schematic diagram illustrating the configuration of a shuttle unit 300 of the test handler 1000 shown in FIG. 1. FIG. 5 is a schematic diagram illustrating the configuration of an align picker unit 220 of the test handler 1000 shown in FIG. 1.

As shown in FIG. 1, the test handler 1000 according to an embodiment of the present disclosure may largely include a loader unit 100, a tester unit 200, and a shuttle unit 300.

As shown in FIG. 1, the loader unit 100 may detach a semiconductor package 1 from a first ring frame 10, on which semiconductor package 1 to be tested by the tester unit 200 are placed or may attach a tested semiconductor package 1 to a second ring frame 20 after testing by the tester unit 200.

Here, the second ring frame 20, to which the tested semiconductor package 1 is attached at the loader unit 100, may either reuse the first ring frame 10 from which the semiconductor package 1 was detached or use a new ring frame. Additionally, depending on the inspection result of the semiconductor package 1 by the tester unit 200, at least two second ring frames 20 may be provided in the loader unit 100 to allow separation and attachment based on whether the package is good or defective.

As shown in FIG. 1, a gripper unit 110 of the loader unit 100 may draw the first ring frame 10, on which a plurality of semiconductor packages 1 to be tested are placed, from a first cassette C1, or may store a second ring frame 20, on which the tested semiconductor packages 1 are placed, into a second cassette C2.

For example, the gripper unit 110 may include a gripper gantry 111 formed to extend in a direction (Y-axis direction) perpendicular to the extension directions (X-axis direction) of the load gantry 141 of the load picker unit 140 and the unload gantry 151 of the unload picker unit 150, which are formed in parallel, and arranged to vertically connect between the load gantry 141 and the unload gantry 151 below them. The gripper unit 110 may include a gripper 112 installed to be slidable along the gripper gantry 111 and formed with a gripping portion 112a to grip one side of the first ring frame 10 or the second ring frame 20. The gripper 112 may draw the first ring frame 10 from the first cassette C1 to a ring frame expander 120 or store the second ring frame 20 from the ring frame stage 130 into the second cassette C2.

As shown in FIGS. 1 and 2, the ring frame expander 120 of the loader unit 100 places the first ring frame 10 drawn from the first cassette C1 by the gripper unit 110 and expands the dicing tape T to which the semiconductor packages 1 are attached, thereby increasing the spacing between the semiconductor packages 1.

For example, the ring frame expander 120 may include an expansion ring 121 for supporting the dicing tape T and a clamp unit 122 for lowering the first ring frame 10. More specifically, the expansion ring 121 may support the dicing tape T between the semiconductor packages 1 and the rim of the first ring frame 10, and the clamp unit 122 may expand the dicing tape T by lowering the first ring frame 10. As a result of this expansion, the spacing between the semiconductor packages 1 may be increased.

A die ejector 123 may be disposed below the dicing tape T supported by the expansion ring 121, for selectively separating the semiconductor packages 1 from the dicing tape T. The die ejector 123 may include vacuum holes (not shown) for vacuum suction of the underside of the dicing tape T, and ejector members (not shown) that raise a target semiconductor package 1 to be picked up, thereby separating it from the dicing tape T.

Additionally, an upper vision unit 143, installed above the ring frame expander 120, may detect the position of the semiconductor packages 1 placed on the dicing tape T of the first ring frame 10 and identify the semiconductor package 1 to be picked up from the first ring frame 10.

Although not shown, the ring frame expander 120 may further include an expander drive unit (not shown) for moving the ring frame expander 120 in the horizontal direction (X-axis) or the vertical direction (Y-axis). The expander drive unit may adjust the position of the ring frame expander 120 so that the semiconductor package 1 to be picked up is aligned above the die ejector 123.

As shown in FIGS. 1 and 2, the load picker unit 140 of the loader unit 100 may pick up the semiconductor package 1 from the first ring frame 10 placed on the ring frame expander 120 and transfer it to the shuttle stage 320 of the shuttle unit 300.

For example, the load picker unit 140 may include a load gantry 141 formed to extend linearly in the horizontal direction (X-axis direction) along one side of the ring frame expander 120 and the ring frame stage 130, which are arranged in a row, and a load picker 142 installed to be slidable along the load gantry 141, to pick up the semiconductor package 1 from the first ring frame 10 placed on the ring frame expander 120, and slide in the horizontal direction (X-axis direction) along the load gantry 141 to place the picked-up semiconductor package 1 onto the shuttle stage 320 of the shuttle unit 300.

As shown in FIGS. 1 and 3, the ring frame stage 130 may accommodate a second ring frame 20 on which the semiconductor package 1, which has completed testing by the tester unit 200 and has been transferred back to the loader unit 100 via the shuttle unit 300, is to be attached.

For example, to allow the semiconductor package 1 to be classified as either good or defective based on the inspection results from the tester unit 200 and reattached to different second ring frames 20 accordingly, it is preferable that at least two ring frame stages 130 be arranged in the loader unit 100. In this manner, a plurality of ring frame stages 130 may be formed and aligned in a row in the horizontal direction (X-axis direction) along with the ring frame expander 120 in the loader unit 100.

Although not shown, the ring frame stage 130 may further include a stage driving unit (not shown) for moving the ring frame stage 130 in the horizontal direction (X-axis direction) or vertical direction (Y-axis direction). The stage driving unit may adjust the position of the ring frame stage 130 so that the position where the tested semiconductor package 1 is to be reattached is located below the unload picker 152, which picks up the semiconductor package 1 from the shuttle unit 300.

As shown in FIGS. 1 and 3, the unload picker unit 150 of the loader unit 100 may pick up the semiconductor package 1, which has been tested by the tester unit 200 and transferred back to the loader unit 100 via the shuttle unit 300, from the shuttle stage 320, and transfer it to the second ring frame 20 placed on the ring frame stage 130, reattaching it to the appropriate second ring frame 20 according to the inspection result (good/defective).

For example, the unload picker unit 150 may include an unload gantry 151 formed to extend linearly in the horizontal direction (X-axis direction) along the opposite side of the ring frame expander 120 and the ring frame stage 130, which are arranged in a row side by side, and arranged in parallel with the load gantry 141 at a predetermined spacing in the vertical direction (Y-axis direction). The unload picker unit 150 may include an unload picker 152 installed to be slidable in the horizontal direction (X-axis direction) along the unload gantry 151, to pick up the semiconductor package 1 placed on the shuttle stage 320, slide along the unload gantry 151, and reattach the semiconductor package 1 to the appropriate second ring frame 20 based on the inspection result (good/defective).

Additionally, the unload picker unit 150 may further include an unload vision inspection unit 153 installed below the movement path of the unload picker 152, to perform a vision inspection of the exterior of the semiconductor package 1 picked up and transferred by the unload picker 152.

For example, the unload vision inspection unit 153 may capture the bottom surface of the semiconductor package 1, which is picked up and transferred by the unload picker 152, from below the unload picker 152. Based on the captured image of the outer surface (edge portion) of the semiconductor package 1, the unload vision inspection unit 153 may determine the pickup position of the semiconductor package 1. As a result, the unload vision inspection unit 153 may detect pickup errors (such as positional deviation in the X-axis or Y-axis direction from the correct pickup position, or rotational error about the Z-axis).

Accordingly, the unload picker 152 may correct the pickup error of the semiconductor package 1 based on the vision inspection result from the unload vision inspection unit 153. The unload picker 152 may offset the semiconductor package 1 from the attachment reference position on the ring frame stage 130 by the pickup error, enabling precise attachment to the second ring frame 20.

As shown in FIGS. 1 and 4, the shuttle unit 300 is installed to extend in the vertical direction (Y-axis direction) to connect the loader unit 100 and the tester unit 200 and is to transfer the semiconductor package 1 to the tester unit 200 or to the loader unit 100. During the transfer, the shuttle unit 300 may also preheat or cool the semiconductor package 1.

For example, the shuttle rail unit 310 of the shuttle unit 300 may be formed to extend in a direction perpendicular to the extension directions of the load gantry 141 and the unload gantry 151, which are formed in parallel. One end of the shuttle rail unit 310 may extend to the operating range of the align picker unit 220 of the tester unit 200.

Additionally, the shuttle stage 320 of the shuttle unit 300 is installed to be slidable along the shuttle rail unit 310 and to transfer the semiconductor package 1 between the loader unit 100 and the tester unit 200.

The shuttle stage 320 may further include a heater unit 321, installed inside the shuttle stage 320, for heating the semiconductor package 1 placed on its upper surface to a preset test temperature before testing. The shuttle stage 320 may further include a cooling unit 322, installed on the side of the shuttle stage 320 and including a nozzle N that blows air A toward the semiconductor package 1 after testing, for cooling the tested semiconductor package 1 to room temperature.

As shown in FIG. 1, the tester unit 200 may test the semiconductor package 1 loaded from the loader unit 100 and unload the tested semiconductor package 1 back to the loader unit 100.

For example, the tester module 210 of the tester unit 200 may perform testing on the semiconductor package 1.

More specifically, the tester module 210 may include a tester main body 211 located on one side of the sliding movement path of a test stage 230 (described below), a tester 212 rotatably installed on the tester main body 211 via a hinge shaft 212a, such that it can be selectively positioned above the test stage 230 along its sliding path, and to provide test signals for electrical testing of the semiconductor package 1, and a probe module 213 installed to be slidable back and forth in a direction facing the sliding movement path of the test stage 230 from the tester main body 211, so that it can be selectively positioned between the tester 212 and the test stage 230, and to electrically connect the tester 212 with the semiconductor package 1 placed on the test stage 230.

Accordingly, the tester 212 may be electrically connected to the semiconductor packages 1 placed on the test stage 230 via the above-described probe module 213. It provides electrical signals to the semiconductor packages 1 and analyzes the output signals from them to determine whether the semiconductor packages 1 on the test stage 230 are good or defective.

As shown in FIGS. 1 and 5, the align picker unit 220 of the tester unit 200 may pick up the semiconductor package 1, which has been transferred to the tester unit 200 via the shuttle unit 300, from the shuttle stage 320 and place it on the test stage 230 for testing, or pick up the tested semiconductor package 1 from the test stage 230 and place it on the shuttle unit 300.

For example, the align gantry 221 of the align picker unit 220 may be formed to extend linearly in the vertical direction (Y-axis direction) between one end of the shuttle unit 300 and a position corresponding to the sliding movement path of the test stage 230.

The align picker 222 of the align picker unit 220 may be installed to be slidable along the align gantry 221 in the vertical direction (Y-axis direction). It may pick up the semiconductor package 1 transferred via the shuttle unit 300 from the shuttle stage 320 and place it on the test stage 230, or pick up the tested semiconductor package 1 from the test stage 230 and place it on the shuttle stage 320 of the shuttle unit 300 to transfer to loader unit 100.

Additionally, the align vision inspection unit 223 of the align picker unit 220 may be installed above the align picker 222, which includes a hollow portion 222a. The align vision inspection unit 223 may perform a vision inspection of the internal pattern on the upper surface of the semiconductor package 1 picked up by the align picker 222 through the hollow portion 222a.

For example, the align vision inspection unit 223 may capture an image of the upper surface of the semiconductor package 1 picked up and transferred by the align picker 222 from above, through the hollow portion 222a that vertically penetrates the align picker 222 (in the Z-axis direction). Based on the internal pattern on the upper surface of the semiconductor package 1, including micro pillar bump 1a and pad 1b, it may determine the pickup position of the semiconductor package 1. Accordingly, it may detect pickup errors (such as deviation in the X-axis or Y-axis directions, or rotational error about the Z-axis) relative to the ideal pickup position.

Accordingly, the align picker 222 may correct the pickup error of the semiconductor package 1 based on the vision inspection result from the align vision inspection unit 223 regarding the internal pattern of the semiconductor package 1. The corrected pickup error may be applied as an offset from the ideal seating position on the test stage 230 (i.e., the test position where the probe of the probe module 213 and the pad 1b of the semiconductor package 1 are accurately connected). By doing so, the placement operation onto the test stage 230 can be performed with high precision, thereby enabling the tester module 210 to conduct precise testing of the semiconductor package 1.

As further shown in FIG. 1, the test stage 230 of the tester unit 200 is installed to be slidable between the align picker unit 220 and the tester module 210, and is to move the semiconductor packages 1 to be tested to a position corresponding to the tester module 210 or to move the tested semiconductor packages 1 to a position corresponding to the align picker unit 220.

The test stage 230 may serve as a type of chuck that supports the semiconductor package 1 during testing by the tester module 210, and it may be a multi-parameter structured chuck that can be temperature-controlled by region to accommodate various parameters.

In addition, the test stage 230 may undergo deformation, such as expansion or contraction, depending on its temperature. As a result of such deformation, even if the align picker 222 places the semiconductor package 1 at the intended seating position, a positioning error may still occur.

Accordingly, the align picker unit 220 may pre-calculate and store deformation data corresponding to the amount of deformation of the test stage 230 at various temperatures. When the align picker unit 220 places the semiconductor package 1 onto the test stage 230, it may calculate the real-time deformation amount of the test stage 230 based on the measured real-time temperature of the test stage 230 and the stored deformation data. It may then offset the placement position of the semiconductor package 1 by the calculated deformation amount to ensure that the semiconductor package 1 is accurately placed on the test stage 230, thereby preventing placement errors due to thermal deformation of the test stage 230.

Additionally, as shown in FIG. 1, two test stages 230 may be provided in a left-right symmetric arrangement relative to the tester module 210 in the tester unit 200.

Accordingly, while one test stage 230 moves toward the tester module 210 to perform the testing process of a semiconductor package 1, the other test stage 230 may move toward the align picker unit 220 to transfer the tested semiconductor package 1 to the loader unit 100 via the shuttle unit 300 and receive a new semiconductor package 1 from the loader unit 100 via the shuttle unit 300. In this way, the logistics process of the semiconductor packages 1 can be efficiently managed, thereby reducing the testing time of semiconductor packages 1 in the test handler 1000.

To accommodate such a dual-structured test stage 230, as shown in FIG. 1, the align picker unit 220 and the shuttle unit 300 may also be formed in a dual structure, with two units arranged symmetrically in the horizontal direction (X-axis direction) relative to the tester module 210.

Additionally, an upper vision inspection device 240 may be installed above the movement path of the test stage 230. During movement of the test stage 230 toward the tester module 210, the upper vision inspection device 240 may inspect the arrangement state of the semiconductor packages 1 placed in multiple rows and columns on the test stage 230 and rotate the test stage 230 as needed to perform alignment.

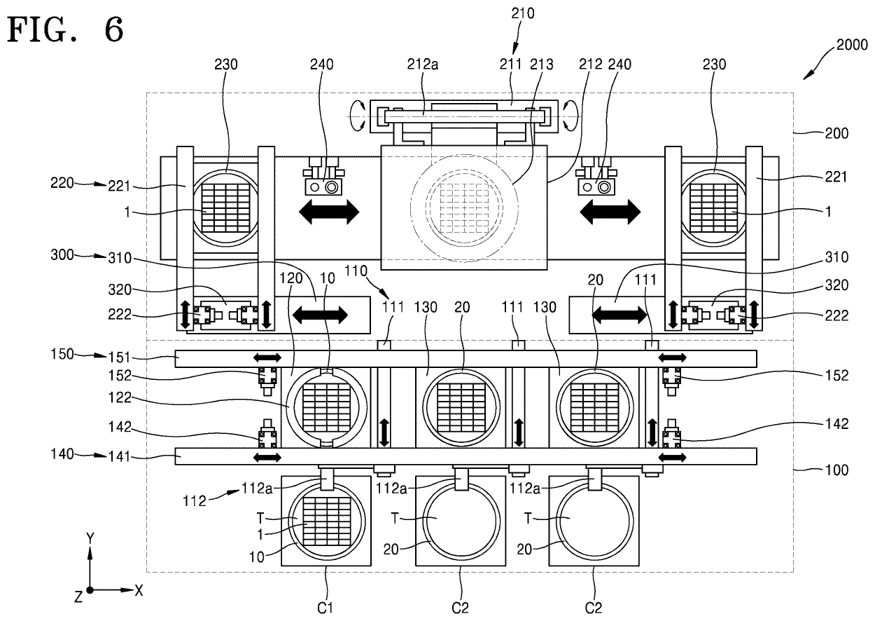

FIG. 6 is a schematic diagram illustrating the configuration of a test handler 2000 according to another embodiment of the present disclosure.

The layout of the loader unit 100, which loads semiconductor packages 1 to be tested into the tester unit 200 or unloads tested semiconductor packages 1, and the shuttle unit 300 is not limited to the configuration shown in FIG. 1. Instead, it may be arranged in various configurations depending on the available installation space.

For example, as shown in FIG. 6, the shuttle unit 300 may be installed to extend in the horizontal direction (X-axis direction), parallel to the load gantry 141 and the unload gantry 151, to connect the loader unit 100 and the tester unit 200. The shuttle unit 300 transfers semiconductor packages 1 to the tester unit 200 or to the loader unit 100 and may preheat or cool the semiconductor packages 1 during transferring the semiconductor packages 1.

For instance, the shuttle rail unit 310 of the shuttle unit 300 may be formed to extend in the horizontal direction (X-axis direction), which is parallel to the extension direction of the load gantry 141 and the unload gantry 151. One end of the shuttle rail unit 310 may extend to reach the operating range of the align picker unit 220 of the tester unit 200, thereby forming a perpendicular intersection with the align picker unit 220.

Accordingly, the shuttle stage 320 of the shuttle unit 300 may be installed to be slidable along the shuttle rail unit 310 in the horizontal direction (X-axis direction), and to transfer the semiconductor packages 1 between the loader unit 100 and the tester unit 200.

By forming the shuttle unit 300 to extend in the horizontal direction (X-axis direction), perpendicular to the extension direction of the gripper gantry 111, the overall layout of the equipment can be optimized, resulting in a reduced footprint of the test handler 2000.

In this case, to ensure that the load picker 142 and the unload picker 152 can reach the operating range of the shuttle stage 320 in the shuttle unit 300, the load gantry 141, on which the load picker 142 is installed to slide in the horizontal direction (X-axis direction), and the unload gantry 151, on which the unload picker 152 is installed to slide in the same direction, may be further to be slidable in the vertical direction (Y-axis direction). To prevent interference between them, the load gantry 141 and the unload gantry 151 may be arranged at different heights in the vertical (Z-axis) direction.

Furthermore, the shuttle stage 320 of the shuttle unit 300 may be installed on the shuttle rail unit 310 to be capable of moving up and down in the vertical direction (Z-axis). Through upward or downward motion, the semiconductor packages 1 may be transferred in a stacked configuration with multiple layers, thereby increasing the transfer efficiency of the semiconductor packages 1.

Hereinafter, a detailed description will be provided regarding a semiconductor package test method using the above-described test handler 1000.

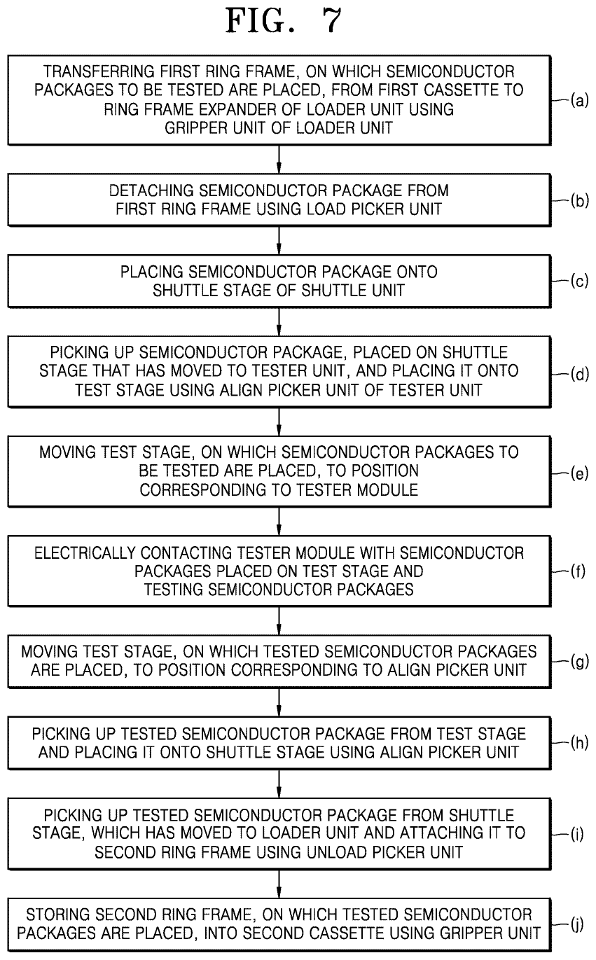

FIG. 7 is a flowchart sequentially illustrating a semiconductor package inspection method according to another embodiment of the present disclosure.

As shown in FIG. 7, a semiconductor package test method according to another embodiment of the present invention may proceed in the sequences of (a) transferring a first ring frame 10, on which the semiconductor packages 1 to be tested are placed, from a first cassette C1 to a ring frame expander 120 of the loader unit 100 using the gripper unit 110 of the loader unit 100; (b) detaching the semiconductor package 1 from the first ring frame 10 using the load picker unit 140; (c) placing the semiconductor package 1 onto a shuttle stage 320 of the shuttle unit 300; (d) picking up the semiconductor package 1, placed on the shuttle stage 320 that has moved to the tester unit 200, and placing it onto a test stage 230 using the align picker unit 220 of the tester unit 200; (e) moving the test stage 230, on which the semiconductor packages 1 to be tested placed, to a position corresponding to a tester module 210; (f) electrically contacting the tester module 210 with the semiconductor packages 1 placed on the test stage 230 and testing the semiconductor packages 1; (g) moving the test stage 230, on which the tested semiconductor packages 1 are placed, to a position corresponding to the align picker unit 220; (h) picking up the tested semiconductor package 1 from the test stage 230 and placing it onto the shuttle stage 320 using the align picker unit 220; (i) picking up the tested semiconductor package 1 from the shuttle stage 320, which has moved to the loader unit 100, and attaching it to a second ring frame 20 using the unload picker unit 150; and (j) storing the second ring frame 20, on which the tested semiconductor packages 1 are placed, into a second cassette C2 using the gripper unit 110.

Accordingly, according to various embodiments of the test handler 1000 and the semiconductor package test method of the present disclosure, as an electrical inspection system for semiconductor packages 1 (HBM chips) having micro pillar bumps, an electrical inspection process can be performed on the semiconductor packages 1 loaded on a first ring frame 10, and based on the determination of whether the packages are good or defective, they can be re-attached to a new second ring frame 20.

In addition, the test stage 230, on which the semiconductor package 1 is placed for the electrical inspection process, is configured as an individual chucking device with a multi-parameter structure (applying a dual chuck configuration), allowing precise hot/cold temperature control of the chuck. Depending on the amount of deformation of the chuck at specific temperatures—such as low, ambient, or high temperature—the align picker unit 220 applies an offset to the placement position of the semiconductor package 1 on the chuck. This allows precise placement of the semiconductor package 1 in response to temperature-induced chuck deformation.

Moreover, the align picker unit 220 is implemented using an align picker 222 with a hollow portion. The align vision inspection unit 223, installed above the align picker 222, performs vision inspection of the internal pattern on the top surface of the semiconductor package 1 picked up by the align picker 222 through the hollow portion 222a, and corrects pickup errors. In addition, the unload vision inspection unit 153, installed below the movement path of the unload picker 152 that re-attaches the inspected semiconductor package 1 to a new second ring frame 20, performs a vision inspection of the underside of the semiconductor package 1 picked up by the unload picker 152 to correct pickup errors. Through the use of vision systems, precise alignment technology for the semiconductor packages 1 can be achieved, thereby further improving the precision of the semiconductor package inspection process.

Thus, the high bandwidth memory (HBM) devices, formed of dies in which multiple memory elements and logic elements are stacked together, can be arranged in precise positions and subjected to an electrical inspection process, thereby improving the test accuracy of the HBM devices. As a result, the test handler 1000 and semiconductor package test method of the present disclosure can precisely classify whether the HBM devices are in good or defective condition.

According to an embodiment of the present disclosure as constructed above, the disclosure serves as an electrical inspection system for semiconductor package (HBM chip) having a micro pillar bump. After performing an electrical inspection process on a semiconductor package loaded on a ring frame, the semiconductor package can be re-attached to a new ring frame according to the determination of whether it is good or defective.

Additionally, to enable the electrical inspection process, the test stage on which the semiconductor package is mounted is composed of an individual chucking device with a multi-parameter structure (with dual chuck application), capable of accommodating various parameters. This configuration enables precise hot/cold temperature control of the chuck. Moreover, depending on the amount of the deformation of the chuck at specific temperatures—such as low, ambient, or high temperatures—the align picker unit applies an offset to the placement position of the semiconductor package on the chuck, thereby allowing for precise placement of the semiconductor package by compensating for temperature-induced chuck deformation.

Furthermore, the align picker unit is implemented as an align picker having a hollow portion, and the align vision inspection unit installed above the align picker performs a vision inspection of the internal pattern on the top surface of the semiconductor package picked up by the align picker through the hollow portion to correct pickup errors. Additionally, the unload vision inspection unit, which is installed below the movement path of the unload picker that re-attaches the inspected semiconductor package to a new ring frame, performs a vision inspection of the bottom exterior of the semiconductor package picked up by the unload picker to correct pickup errors. Through the use of vision systems, precise alignment of the semiconductor package can be achieved, thereby further enhancing the accuracy of the semiconductor package inspection process.

In this manner, high bandwidth memory (HBM) devices, which are formed of a die in which a plurality of memory devices and logic devices are stacked together, can be precisely aligned and electrically tested. As a result, the test accuracy for high bandwidth memory devices can be improved, enabling the test handler and the test method for semiconductor package to precisely classify whether the HBM devices are in good condition or defective condition. Of course, the scope of the present disclosure is not limited by these effects.

The present disclosure has been described with reference to the embodiments illustrated in the drawings, but these are merely exemplary. It will be understood by those of ordinary skill in the art that various modifications and equivalent other embodiments may be possible from this disclosure. Therefore, the true technical scope of the present disclosure should be defined by the technical spirit of the appended claims.

What is claimed is:

1. A test handler comprising:
a loader unit to detach a semiconductor package to be tested from a first ring frame on which the semiconductor packages to be tested are placed, or to attach a tested semiconductor package to a second ring frame;
a tester unit to test the semiconductor package loaded from the loader unit and to unload the tested semiconductor package back to the loader unit; and
a shuttle unit installed to connect the loader unit and the tester unit, to transfer the semiconductor package to the tester unit or to the loader unit, and to preheat or cool the semiconductor package during transfer.

2. The test handler of claim 1, wherein the loader unit comprises:
a gripper unit to draw the first ring frame, on which a plurality of semiconductor packages to be tested are placed, from a first cassette, or to store the second ring frame, on which the tested semiconductor packages are placed, into a second cassette;
a ring frame expander to place the first ring frame drawn from the first cassette and to expand a dicing tape to which the semiconductor packages are attached so as to increase spacing between the semiconductor packages;
a ring frame stage on which the second ring frame to which the tested semiconductor packages are to be attached is placed;
a load picker unit to pick up the semiconductor package from the first ring frame placed on the ring frame expander and to transfer it to the shuttle unit; and
an unload picker unit to pick up the semiconductor package tested by the tester unit and transferred back to the loader unit via the shuttle unit and to transfer it onto the second ring frame placed on the ring frame stage.

3. The test handler of claim 2, wherein the load picker unit comprises:
a load gantry formed to extend linearly along one side of the ring frame expander and the ring frame stage, which are arranged in a row; and
a load picker installed to be slidable along the load gantry, to pick up the semiconductor package from the first ring frame placed on the ring frame expander,
wherein the unload picker unit comprises:
an unload gantry formed to extend linearly along an opposite side of the ring frame expander and the ring frame stage, arranged in a row, so as to be parallel to the load gantry; and
an unload picker installed to be slidable along the unload gantry, to pick up the semiconductor package placed on the shuttle unit,
wherein the gripper unit comprises:
a gripper gantry formed to extend in a direction perpendicular to extension directions of the load gantry and the unload gantry, which are formed in parallel, and to connect the load gantry and the unload gantry; and
a gripper installed to be slidable along the gripper gantry, formed with a gripping portion to grip one side of the first or second ring frame, and to draw the first ring frame from the first cassette to the ring frame expander or to store the second ring frame from the ring frame stage into the second cassette.

4. The test handler of claim 3, wherein the unload picker unit further comprises:
an unload vision inspection unit installed below a path of movement of the unload picker and to perform a vision inspection of an exterior of the semiconductor package picked up and transferred by the unload picker, and wherein the unload picker is to correct a pickup error of the semiconductor package based on a result of the vision inspection by the unload vision inspection unit.

5. The test handler of claim 3, wherein the shuttle unit comprises:
a shuttle rail unit formed to extend in the direction perpendicular to the extension directions of the load gantry and the unload gantry, which are formed in parallel, and extending to the tester unit; and
a shuttle stage installed to be slidable along the shuttle rail unit and to transfer the semiconductor package between the loader unit and the tester unit.

6. The test handler of claim 5, wherein the shuttle stage comprises:
a heater unit installed inside the shuttle stage, to heat the semiconductor package placed on an upper surface of the shuttle stage; and
a cooling unit including a nozzle installed on a side of the shuttle stage, to spray air toward the semiconductor package placed on the upper surface of the shuttle stage to cool the semiconductor package.

7. The test handler of claim 1, wherein the tester unit comprises:
a tester module to test the semiconductor package;
an align picker unit to pick up the semiconductor package transferred to the tester unit via the shuttle unit; and
a test stage installed to be slidable between the align picker unit and the tester module, to move the semiconductor package to a position corresponding to the tester module or to a position corresponding to the align picker unit,
wherein the align picker unit places the semiconductor package on the test stage for testing, or to pick up the tested semiconductor package from the test stage and place it on the shuttle unit.

8. The test handler of claim 7, wherein the align picker unit comprises:
an align gantry formed to extend linearly in a direction between one end of the shuttle unit and a position corresponding to a sliding movement path of the test stage;
an align picker installed to be slidable along the align gantry, to pick up the semiconductor package transferred via the shuttle unit and place it onto the test stage, or to pick up the tested semiconductor package from the test stage and place it onto the shuttle unit; and
an align vision inspection unit installed above the align picker having a hollow portion, to perform a vision inspection of an internal pattern on an upper surface of the semiconductor package picked up by the align picker through the hollow portion,
wherein the align picker is to correct a pickup error of the semiconductor package based on a result of the vision inspection of the internal pattern by the align vision inspection unit.

9. The test handler of claim 8, wherein the align picker unit is to pre-calculate and store deformation data for the test stage according to temperature; and when placing the semiconductor package on the test stage, to calculate real-time deformation amount of the test stage based on a measured real-time temperature and the deformation data; and to offset a placement position of the semiconductor package by the real-time deformation amount, thereby placing the semiconductor package on the test stage.

10. A method for testing semiconductor packages using a test handler comprising a loader unit to detach a semiconductor package to be tested from a first ring frame on which the semiconductor packages to be tested are placed, or to attach a tested semiconductor package to a second ring frame, a tester unit to test the semiconductor package loaded from the loader unit and to unload the tested semiconductor package back to the loader unit, and a shuttle unit installed to connect the loader unit and the tester unit, to transfer the semiconductor package to the tester unit or to the loader unit, and to preheat or cool the semiconductor package during transfer, the method comprising steps of:
(a) transferring the first ring frame, on which the semiconductor packages to be tested are placed, from a first cassette to a ring frame expander of the loader unit using a gripper unit of the loader unit;
(b) detaching the semiconductor package from the first ring frame using a load picker unit;
(c) placing the semiconductor package onto a shuttle stage of the shuttle unit;
(d) picking up the semiconductor package, placed on the shuttle stage that has moved to the tester unit, and placing it onto a test stage using an align picker unit of the tester unit;
(e) moving the test stage, on which the semiconductor packages to be tested are placed, to a position corresponding to a tester module;
(f) electrically contacting the tester module with the semiconductor packages placed on the test stage and testing the semiconductor packages;
(g) moving the test stage, on which the tested semiconductor packages are placed, to a position corresponding to the align picker unit;
(h) picking up the tested semiconductor package from the test stage and placing it onto the shuttle stage using the align picker unit;
(i) picking up the tested semiconductor package from the shuttle stage, which has moved to the loader unit and attaching it to the second ring frame using an unload picker unit; and
(j) storing the second ring frame, on which the tested semiconductor packages are placed, into a second cassette using the gripper unit.
